(19) United States
(12) Patent Application Publication
(10) Pub. No.: US 2025/0011229 A1
(43) Pub. Date: Jan. 9, 2025

(54) METHOD FOR MANUFACTURING GLASS PLATE

(71) Applicant: NIPPON ELECTRIC GLASS CO., LTD., Shiga (JP)

(72) Inventor: Hiroaki TANAKA, Shiga (JP)

(21) Appl. No.: 18/713,396

(22) PCT Filed: Nov. 18, 2022
(86) PCT No.: PCT/JP2022/042814

§ 371 Date: May 24, 2024

(30) Foreign Application Priority Data
Dec. 3, 2021 (JP) 2021-197047

(51) Int. Cl. C03C 23/00; C03C 15/00

(52) U.S. Cl. CPC C03C 23/0025; C03C 15/00

(57) ABSTRACT

A method includes a modifying step of modifying a preset formation part for a through hole by irradiation of laser light, and an etching step of etching a first main surface and a second main surface while immersing a glass sheet in an etchant, to form the through hole in the preset formation part, after the modifying step. The etching step includes a first etching step of etching the glass sheet in which the preset formation part does not penetrate, and a second etching step of etching the glass sheet in which the preset formation part penetrates, after the first etching step. An average relative velocity of the etchant with respect to the glass sheet in the second etching step is higher than that in the first etching step.

### TECHNICAL FIELD

The present invention relates to a method for manufacturing a glass sheet having a through hole.

### BACKGROUND ART

A glass sheet having a fine through hole for interconnection (through-via or the like) is used as a substrate of, for example, a tiled display (micro LED and the like), a bezel-less display, a glass interposer, or the like.

A method for manufacturing this type of glass sheet having a through hole includes, for example, a modifying step of modifying a position where a through hole is to be formed in the glass sheet by irradiation of laser light, to form a modified part, and an etching step of etching a preset formation part including the modified part, to form a through hole (for example, refer to Patent Literatures 1 and 2).

### CITATION LIST

Patent Literature 1: JP 2018-199605 A
Patent Literature 2: JP 2020-066551 A

### SUMMARY OF INVENTION

### Technical Problem

According to the above-mentioned manufacturing method, the modified part formed in the modifying step has a higher etching rate than that of a non-modified part, and hence is selectively removed in the etching step. Thus, when the modified part is formed so as to extend from a first main surface to a second main surface along a sheet-thickness direction of the glass sheet, it is possible to form a through hole by etching.

When a though hole is formed in the above-mentioned manner, a part closer to a main surface of the glass sheet is in contact with an etchant for a longer time, and is accordingly more susceptible to etching. Thus, in the through hole, the part closer to the main surface has a larger hole diameter than that at a central part along the sheet-thickness direction, so that an inner wall surface of the through hole is tapered. Such a large hole diameter in the main surface of the glass sheet can cause a problem of incapability of forming an ultrafine pattern in the main surface of the glass sheet, or the like.

An inclination angle of the inner wall surface of the through hole with respect to a direction perpendicular to the sheet-thickness direction (an angle formed by a direction perpendicular to the sheet-thickness direction and the inner wall surface of the through hole, which is hereinafter simply referred to as “inclination angle of the inner wall surface”) varies with an etching condition.

It is an object of the present invention to increase the inclination angle of the inner wall surface of the through hole.

### Solution to Problem

(1) According to the present invention, which has been devised in order to achieve the above-mentioned object, there is provided a method for manufacturing a glass sheet having a first main surface, a second main surface, and a through hole penetrating between the first main surface and the second main surface, the method comprising: a modifying step of modifying a preset formation part for the through hole by irradiation of laser light; and an etching step of etching the glass sheet while immersing the glass sheet in an etchant, to form the through hole in the preset formation part, after the modifying step, wherein the etching step comprises: a first etching step of etching the glass sheet in which the preset formation part does not penetrate; and a second etching step of etching the glass sheet in which the preset formation part penetrates, after the first etching step, and wherein an average relative velocity of the etchant with respect to the glass sheet in the second etching step is higher than that in the first etching step.

As a result of extensive studies, the inventors of the present invention has found that the inclination angle of the inner wall surface of the through hole to be finally formed is determined by (a) a magnitude of the inclination angle of the inner wall surface of a preset formation part at the time of penetration of the preset formation part, and (b) a rate of change in the inclination angle of the inner wall surface of the preset formation part after penetration of the preset formation part. That is, in order to increase the inclination angle of the through hole to be finally formed, it is important to (a′) increase the inclination angle of the inner wall surface of the preset formation part at the time of penetration of the preset formation part (bring the inclination angle closer to) 90° and to (b′) cause a change in a positive direction in the rate of change in the inclination angle of the inner wall surface of the preset formation part after penetration of the preset formation part.

The preset formation part modified by laser irradiation is in a state of being susceptible to etching. However, under a state in which the preset formation part is not penetrating, that is, under a state in which the preset formation part remains being a bottomed recessed portion, an etchant cannot flow back and forth along the sheet-thickness direction in the preset formation part. Thus, even when the average relative velocity of the etchant with respect to the glass sheet is increased under the above-described state, an exchange efficiency of the etchant in the recessed portion of the preset formation part as compared to the exchange efficiency of the etchant in the main surface of the glass sheet does not improve. In other words, even when the average relative velocity of the etchant is increased, the time required for exchange of the etchant in the recessed portion of the preset formation part is not shortened as compared to that in the main surface of the glass sheet. Consequently, only etching of a part near the main surface of the glass sheet is promoted, so that the hole diameter in the main surface is preferentially increased. This results in a decrease in the inclination angle of the inner wall surface of the preset formation part at the time of penetration. Meanwhile, under the state in which the preset formation part is penetrating, an etchant can flow back and forth along the sheet-thickness direction in the preset formation part. Thus, when the average relative velocity of the etchant with respect to the glass sheet is increased under the above-mentioned state, the exchange efficiency of an etchant in the preset formation part, as well as the exchange efficiency of an etchant in the main surface of the glass sheet, are improved. Consequently, a change in the positive direction in the rate of change in the inclination angle of the inner wall surface of the preset formation part after penetration can be changed. Thus, when the average relative velocity of the etchant with respect to the glass sheet in the second etching step is made higher than that in the first etching step as in the above-described configuration, it is possible to increase the inclination angle of the inner wall surface of the preset formation part at the time of penetration of the preset formation part, and to cause a change in the positive direction in the rate of change in the inclination angle of the inner wall surface of the preset formation part after penetration of the preset formation part. This enables an increase in the inclination angle of the inner wall surface of the through hole.

(2) In the configuration of the above-mentioned item (1), it is preferred that the second etching step be started when the preset formation part penetrates.

With this configuration, the speed of progress of etching in the preset formation part can be increased from the time when the preset formation part penetrates. Thus, the rate of change in the inclination angle of the inner wall surface of the preset formation part after penetration of the preset formation part can be changed more in the positive direction. This enables an increase in the inclination angle of the inner wall surface of the through hole.

(3) In the configuration of the above-mentioned item (1) or (2), in the etching step, the etchant may be stirred, and an average stirring speed of the etchant in the second etching step may be made higher than that in the first etching step.

With this configuration, the average relative velocity of the etchant with respect to the glass sheet in the second etching step can be made higher than that in the first etching step.

(4) In the configuration of the above-mentioned items (1) to (3), in the etching step, the glass sheet may be moved in the etchant, and an average movement speed of the glass sheet in the second etching step may be made higher than that in the first etching step.

With this configuration, the average relative velocity of the etchant with respect to the glass sheet in the second etching step can be made higher than that in the first etching step.

(8) According to the present invention, which has been devised in order to achieve the above-mentioned object, there is provided a method for manufacturing a glass sheet having a first main surface, a second main surface, and a through hole penetrating between the first main surface and the second main surface, the method comprising: a modifying step of modifying a preset formation part for the through hole by irradiation of laser light; and an etching step of performing etching by jetting an etchant to each of the first main surface and the second main surface, to form the through hole in the preset formation part, after the modifying step, wherein the etching step comprises: a first etching step of etching the glass sheet in which the preset formation part does not penetrate; and a second etching step of etching the glass sheet in which the preset formation part penetrates, after the first etching step, and wherein an average jetting pressure of the etchant to the glass sheet in the second etching step is higher than that in the first etching step.

With this configuration, for reasons similar to the reasons described above, when the average jetting pressure applied by jetting of the etchant to the glass sheet in the second etching step is made higher than that in the first etching step, it is possible to increase the inclination angle of the inner wall surface of the preset formation part at the time of penetration of the preset formation part, and to cause a change in the positive direction in the rate of change in the inclination angle of the inner wall surface of the preset formation part after penetration of the preset formation part. This enables an increase in the inclination angle of the inner wall surface of the through hole.

(6) In the configuration of the above-mentioned item (5), it is preferred that the second etching step be started when the preset formation part penetrates.

With this configuration, the inclination angle of the inner wall surface of the through hole can be more reliably increased.

### Advantageous Effects of Invention

According to the present invention, the inclination angle of the inner wall surface of the through hole can be increased.

### BRIEF DESCRIPTION OF DRAWINGS

FIG. 1 is a flowchart for illustrating a method for manufacturing a glass sheet according to a first embodiment.

FIG. 2 is a sectional view for illustrating a modifying step included in the method for manufacturing a glass sheet according to the first embodiment.

FIG. 3 is a sectional view for illustrating a first etching step included in the method for manufacturing a glass sheet according to the first embodiment.

FIG. 4 is a sectional view for illustrating a second etching step included in the method for manufacturing a glass sheet according to the first embodiment.

FIG. 5 is a sectional view of a glass sheet during the first etching step included in the method for manufacturing a glass sheet according to the first embodiment.

FIG. 6 is a sectional view of a glass sheet during the second etching step included in the method for manufacturing a glass sheet according to the first embodiment, and shows a state of the glass sheet at the time of penetration of a preset formation part.

FIG. 7 is a sectional view of a glass sheet having a through hole manufactured by the method for manufacturing a glass sheet according to the first embodiment.

FIG. 8 is a sectional view for illustrating a first etching step and a second etching step included in a method for manufacturing a glass sheet according to a second embodiment.

FIG. 9 is a side view for illustrating a first etching step included in a method for manufacturing a glass sheet according to a third embodiment.

FIG. 10 is a side view for illustrating a second etching step included in the method for manufacturing a glass sheet according to the third embodiment.

FIG. 11 is a side view for illustrating a first etching step and a second etching step included in a method for manufacturing a glass sheet according to a fourth embodiment.

FIG. 12 is a graph for showing a relationship between a taper angle of a preset formation part and an etching time before penetration of the preset formation part.

FIG. 13 is a graph for showing a relationship between an etching rate of a main surface and a stirring speed before penetration of a preset formation part.

FIG. 14 is a graph for showing a relationship between an etching rate of a preset formation part and a stirring speed before penetration of the preset formation part.

FIG. 15 is a graph for showing a relationship between a taper angle of a preset formation part and a stirring speed at the time of penetration of the preset formation part.

FIG. 16 is a graph for showing a relationship between a rate of change in a taper angle of a preset formation part and a stirring speed after penetration of the preset formation part.

### DESCRIPTION OF EMBODIMENTS

Now, embodiments of the present invention are described with reference to the drawings. Overlapping description may be omitted by denoting corresponding constituent elements in the embodiments by the same reference symbols. When only part of a configuration is described in each of the embodiments, a configuration in other embodiments that has already been described may be adopted for other parts of the configuration. In addition, configurations may be combined in a combination explicit in the description of each of the embodiments, and not only that, part of configurations of a plurality of the embodiments may be combined in an even implicit combination as long as the combination has no particular disadvantage.

### First Embodiment

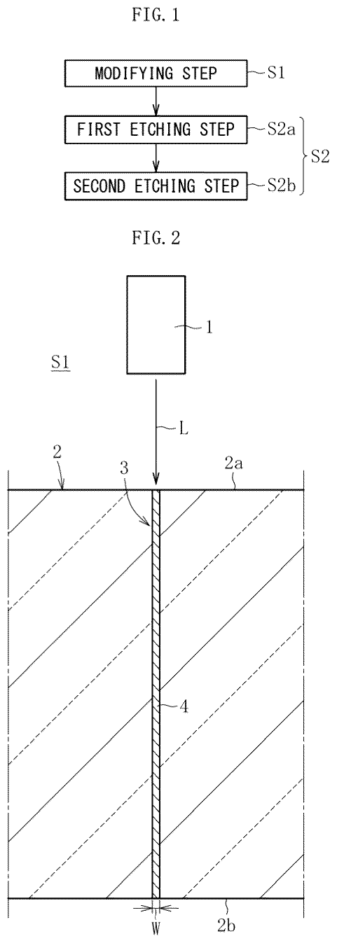

As illustrated in FIG. 1, a method for manufacturing a glass sheet according to a first embodiment comprises a modifying step S1 and an etching step S2, which comprises a first etching step S2a and a second etching step S2b, that are performed in the stated order.

As illustrated in FIG. 2, the modifying step S1 is a step of modifying a preset formation part 3 for a through hole in a glass sheet 2 with the use of laser light L radiated from a laser device 1. The preset formation part 3 having been modified comprises a modified part 4 extending along a sheet-thickness direction. The modified part 4 has a property of being susceptible to etching and has a higher etching rate than that of a non-modified part. It is preferred that the modified part 4 be formed continuously along the sheet-thickness direction, but may be formed intermittently along the sheet-thickness direction. When a plurality of through holes are formed in the glass sheet 2, a plurality of preset formation parts 3 comprising the modified part 4 are also formed.

The type and irradiation condition of the laser light L are not limited to any particular type and any particular condition as long as the modified part 4 can be formed in the preset formation part 3 for a through hole in the glass sheet 2. In the first embodiment, the laser light L is short-pulse laser light (picosecond laser light, nanosecond laser light, or femtosecond laser light). A diameter W of the modified part 4 can be adjusted by a spot diameter of the laser light L.

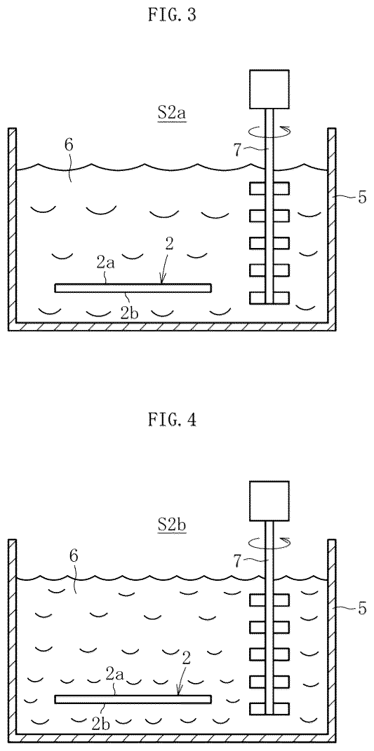

As illustrated in FIG. 3 and FIG. 4, the etching step S2 is a step of etching the glass sheet 2, to form a through hole penetrating between a first main surface 2a and a second main surface 2b of the glass sheet 2 along the sheet-thickness direction in the preset formation part 3 comprising the modified part 4. In the etching step S2, the glass sheet 2 is immersed in an etchant 6 stored in an etching vessel 5, and etching is caused to progress from both sides of the glass sheet 2, that is, from the first main surface 2a and the second main surface 2b, simultaneously.

More specifically, the etching step S2 comprises the first etching step S2a (see FIG. 3) of etching the glass sheet 2 in which the preset formation part 3 does not penetrate, and the second etching step S2b (see FIG. 4) of etching the glass sheet 2 in which the preset formation part 3 penetrates, after the first etching step S2a. In the first etching step S2a and the second etching step S2b, the same etching vessel 5 in which the etchant 6 is stored is used. The etching vessel used in the first etching step S2a may be different from the etching vessel used in the second etching step S2b.

An average relative velocity (hereinafter referred to as “second average relative velocity”) V2 of the etchant 6 with respect to the glass sheet 2 in the second etching step S2b is higher than an average relative velocity (hereinafter referred to as “first average relative velocity”) V1 of the etchant 6 with respect to the glass sheet 2 in the first etching step S2a.

Examples of a method for making the second average relative velocity V2 higher than the first average relative velocity V1 include a method of stirring the etchant 6 and a method of moving the glass sheet 2 in the etchant 6. The method of stirring the etchant 6 and the method of moving the glass sheet 2 in the etchant 6 may be used in combination in order to make the second average relative velocity V2 higher than the first average relative velocity V1.

Examples of the method of stirring the etchant 6 include a method of shaking a louver and a method of vibrating the etchant 6 with the use of ultrasonic waves. In the first embodiment, a method of rotating a stirring member (including screw rotation) 7 is adopted. In the example illustrated in the drawings, the stirring member 7 is placed beside the glass sheet 2, but the position where the stirring member 7 is to be placed is not limited to any particular position. The stirring member 7 may be placed below the glass sheet 2, or may be placed above the glass sheet. When the etchant 6 is stirred, it is preferred that an average stirring speed (referred to as “second average stirring speed”) of the etchant 6 during the second etching step S2b be made higher than an average stirring speed (referred to as “first average stirring speed”) of the etchant 6 during the first etching step S2a in order to make the second average relative velocity V2 higher than the first average relative velocity V1. Here, the term “average stirring speed” means an average rotation speed of the stirring member 7 when the stirring member 7 is used. The position where the stirring member 7 is placed is not limited to any particular position.

Examples of the method of moving the glass sheet 2 in the etchant 6 include a method of shaking the glass sheet 2 in the etchant 6 and a method of rotating the glass sheet 2 in the etchant 6. When the glass sheet 2 is moved in the etchant 6, it is preferred that an average movement speed (referred to as “second average movement speed”) of the glass sheet 2 during the second etching step S2b be made higher than an average movement speed (referred to as “first average movement speed”) of the glass sheet 2 during the first etching step S2a in order to make the second average relative velocity V2 higher than the first average relative velocity V1.

The second etching step S2b is started when the preset formation part 3 penetrates along the sheet-thickness direction. Thus, when the preset formation part 3 penetrates along the sheet-thickness direction, the average relative velocity of the etchant 6 with respect to the glass sheet 2 is changed from the first average relative velocity V1 to the second average relative velocity V2.

In the first embodiment, an etching time taken for the preset formation part 3 to penetrate under the same etching condition is measured in advance, and, when the measured time elapses, it is assumed that the preset formation part 3 has penetrated. Then, the second etching step S2b is started. It may be observed in real time when the preset formation part 3 penetrates, with the use of a camera or the like, and the second etching step S2b may be started when penetration of the preset formation part 3 is observed.

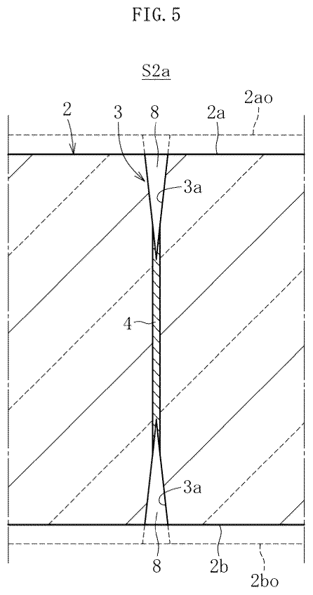

The reasons for making the second average relative velocity V2 in the second etching step S2b higher than the first average relative velocity V1 in the first etching step S2a are as follows. In FIG. 5 to FIG. 7, reference symbols, “2ao” and “2bo” denote the positions of the main surfaces 2a and 2b before etching.

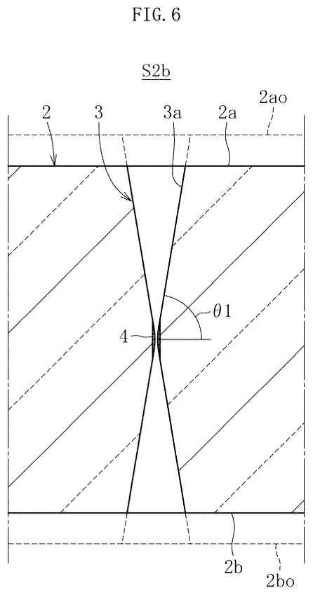

As illustrated in FIG. 5, in the first etching step S2a, the preset formation part 3 comprising the modified part 4 is gradually removed by etching. However, in the first etching step S2a, the preset formation part 3 does not penetrate and forms a bottomed recessed portion 8. Under this state, the etchant 6 cannot flow back and forth along the sheet-thickness direction in the preset formation part 3. Thus, even when the first average relative velocity V1 is increased, the exchange efficiency of the etchant 6 in the recessed portion 8 of the preset formation part 3 does not improve. With such a low exchange efficiency of the etchant 6, the etchant 6 in the recessed portion 8 of the preset formation part 3 is gradually contaminated by reaction products (sludge). This causes a decrease in a ratio R1/R2, where R1 represents the etching rate of the preset formation part 3 and R2 represents the etching rate of the main surfaces 2a and 2b. Consequently, only etching of parts near the main surfaces 2a and 2b of the glass sheet 2 is promoted, which results in a decrease in an inclination angle (also referred to as “taper angle”) θ1 (see FIG. 6) of an inner wall surface 3a of the preset formation part 3 at the time of penetration.

Meanwhile, as illustrated in FIG. 6, in the second etching step S2b, the preset formation part 3 is in a state of penetrating. Under this state, the etchant 6 can freely flow back and forth along the sheet-thickness direction in the preset formation part 3. Thus, when the second average relative velocity V2 is increased, the exchange efficiency of the etchant 6 in the preset formation part 3, as well as the exchange efficiency of the etchant 6 in the main surfaces 2a and 2b of the glass sheet 2, are improved. Consequently, etching of the preset formation part 3, as well as etching of the parts near the main surfaces 2a and 2b of the glass sheet 2, are promoted. This enables shortening of an etching time required to attain a desired hole diameter while reducing a change in the inclination angle θ1 of the inner wall surface 3a of the preset formation part 3 after penetration.

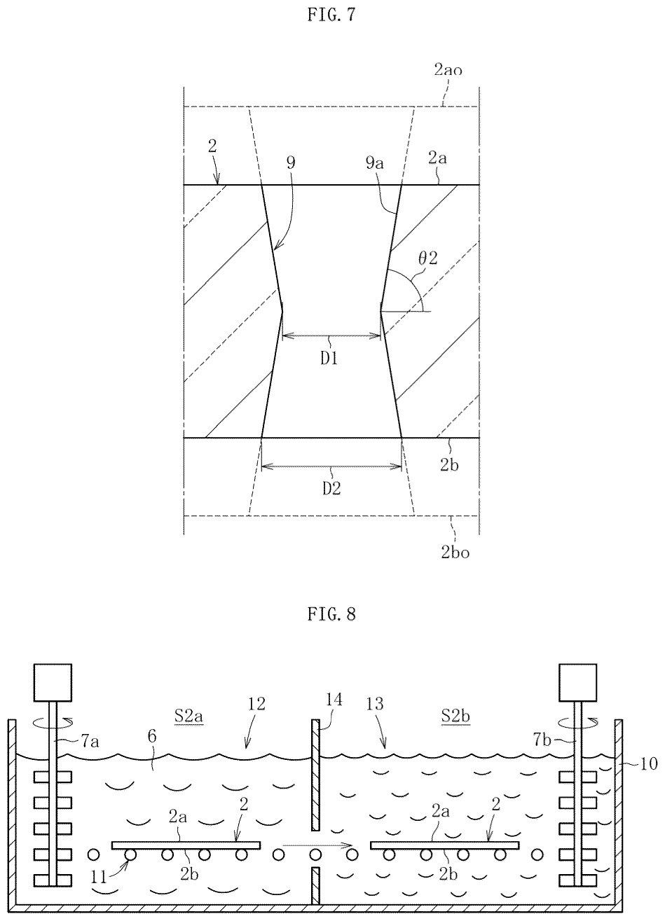

For the reasons described above, the second average relative velocity V2 in the second etching step S2b is made higher than the first average relative velocity V1 in the first etching step S2a. Then, by doing so, it is possible to (1) increase the inclination angle θ1 of the inner wall surface 3a of the preset formation part 3 at the time of penetration of the preset formation part 3 and (2) cause a change in the positive direction in the rate of change in the inclination angle θ1 of the inner wall surface 3a of the preset formation part 3 after penetration of the preset formation part 3. This enables an increase in an inclination angle (also referred to as “taper angle”) 02 of an inner wall surface Sa of a through hole 9 to be finally formed in the glass sheet 2, as illustrated in FIG. 7.

A hole diameter of the through hole 9 at the central part thereof along the sheet-thickness direction is a minimum hole diameter D1, and a hole diameter of the through hole 9 at the main surfaces 2a and 2b is a maximum hole diameter D2.

### Second Embodiment

As illustrated in FIG. 8, a method for manufacturing a glass sheet according to a second embodiment is different from the method for manufacturing a glass sheet according to the first embodiment in conveying the glass sheet 2 being immersed in the etchant 6 in the etching step S2.

In the second embodiment, the etchant 6 is stored in an etching vessel. 10 that is elongate along a conveying direction in which the glass sheet 2 is conveyed. The glass sheet 2 is conveyed by a conveying device 11 such as a roller while being immersed in the etchant 6. In a conveying path for the glass sheet 2, the first etching step S2a is performed in a first area 12 on an upstream side of a position where the preset formation part 3 penetrates, along the conveying direction, and the second etching step S2b is performed in a second area 13 including the position where the preset formation part 3 penetrates and a downstream side thereof along the conveying direction. That is, the average relative velocity of the etchant 6 with respect to the glass sheet 2 is set to the first average relative velocity V1 that is relatively low in the first area 12, and is set to the second average relative velocity V2 that is relatively high in the second area 13.

In this case, an average stirring speed of a stirring member 7b in the second area 13 may be made higher than an average stirring speed of a stirring member 7a in the first area 12. Further, an average movement speed of the glass sheet 2 moved by the conveying device 11 in the second area 13 may be made higher than an average movement speed of the glass sheet 2 moved by the conveying device 11 in the first area 12. Other methods described in the first embodiment can be also applied to a method for adjusting the average relative velocity of the etchant 6 with respect to the glass sheet 2 in each of the areas 12 and 13.

In the second embodiment, between the first area 12 and the second area 13, there is provided a partition wall 14 that suppresses flow of the etchant 6 between the both areas. With this configuration, each of the areas 12 and 13 is partitioned by the partition wall 14, which makes it easier to individually adjust the average relative velocity of the etchant 6 with respect to the glass sheet 2 in each of the areas 12 and 13. The partition wall 14 may be omitted.

### Third Embodiment

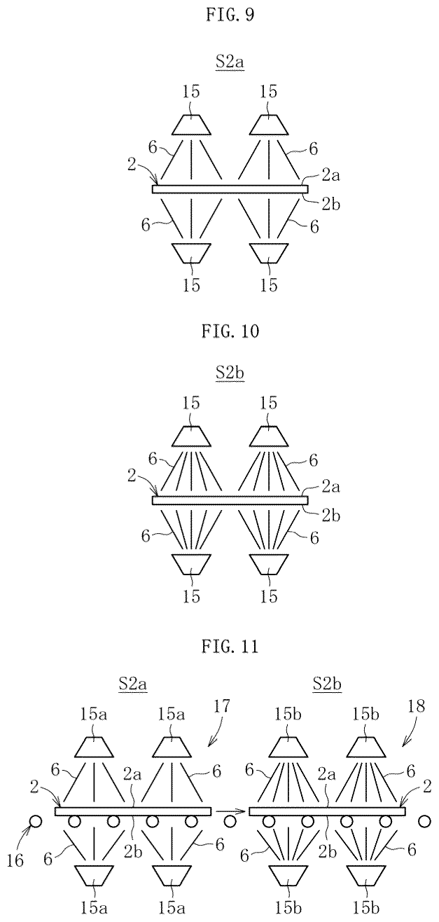

As illustrated in FIG. 9 and FIG. 10, a method for manufacturing a glass sheet according to a third embodiment is different from the methods for manufacturing a glass sheet according to the first and second embodiments in jetting the etchant 6 to the first main surface 2a and the second main surface 2b of the glass sheet 2, instead of immersing the glass sheet 2 in the etchant 6, in the etching step S2.

In the third embodiment, the etching step S2 comprises the first etching step S2a (see FIG. 9) of performing etching by jetting the etchant 6 from a nozzle 15 to the first main surface 2a and the second main surface 2b of the glass sheet 2 in which the preset formation part 3 does not penetrate, and the second etching step S2b (see FIG. 10) of performing etching by jetting the etchant 6 from the nozzle 15 to the first main surface 2a and the second main surface 2b of the glass sheet 2 in which the preset formation part 3 penetrates, after the first etching step S2a.

An average jetting pressure (hereinafter referred to as “second average jetting pressure”) Q2 of the etchant 6 to the glass sheet 2 in the second etching step S2b is higher than an average jetting pressure (hereinafter referred to as “first average jetting pressure”) Q1 of the etchant 6 to the glass sheet 2 in the first etching step S2a.

The second etching step S2b is started when the preset formation part 3 penetrates along the sheet-thickness direction. That is, when the preset formation part 3 penetrates along the sheet-thickness direction, the average jetting pressure of the etchant 6 to the glass sheet 2 is changed from the first average jetting pressure Q1 to the second average jetting pressure Q2.

### Fourth Embodiment

As illustrated in FIG. 11, a method for manufacturing a glass sheet according to a fourth embodiment is different from the method for manufacturing a glass sheet according to the third embodiment in jetting the etchant 6 to the glass sheet 2 being conveyed in the etching step S2.

In the fourth embodiment, the glass sheet 2 is conveyed toward the downstream side along the conveying direction by a conveying device 16. On the conveying path for the glass sheet 2, the etchant 6 is jetted to the first main surface 2a and the second main surface 2b of the glass sheet 2 from nozzles 15a and 15b, respectively. In the conveying path for the glass sheet 2, the first etching step S2a is performed in a first area 17 on the upstream side of the position where the preset formation part 3 penetrates, and the second etching step S2b is performed in a second area 18 including the position where the preset formation part 3 penetrates and the downstream side thereof. That is, the average jetting pressure of the etchant 6 to the glass sheet 2 is set to the first average jetting pressure Q1 that is relatively low in the first area 17, and is set to the second average jetting pressure Q2 that is relatively high in the second area 18.

In this case, the amount of the etchant 6 jetted from the nozzle 15b in the second area 18 per unit time may be made larger than the amount of the etchant 6 jetted from the nozzle 15a in the first area 17 per unit time. Further, the number of the nozzles 15b in the second area 18 may be increased relative to the number of the nozzles 15a in the first area 17.

The present invention is not limited to the configurations of the above-mentioned embodiments. In addition, the action and effect of the present invention are not limited to those described above. The present invention may be modified in various forms within the range not departing from the spirit of the present invention.

The second etching step S2b may be started before penetration of the preset formation part 3 (for example, several minutes before penetration). Alternatively, the second etching step S2b may be started after penetration of the preset formation part 3 (for example, several minutes after penetration). That is, the timing of starting the second etching step S2b is not limited to any particular timing as long as a step of etching the glass sheet 2 in which the preset formation part 3 penetrates is included. However, from the viewpoint of maximizing the inclination angle θ2 of the inner wall surface 9a of the through hole 9 to be finally formed, it is preferred that the second etching step S2b be started when the preset formation part 3 penetrates.

In the etching step S2, the glass sheets 2 may be etched one by one, or a plurality of glass sheets 2 may be etched simultaneously. Further, when the glass sheet 2 is etched while being conveyed in the etching step S2, the shape of the conveying path for the glass sheet 2 is not limited to a linear shape, and may be a curved shape such as an annular shape.

### Examples

In the following, the present invention is described in detail with reference to examples, but the present invention is not limited to these examples.

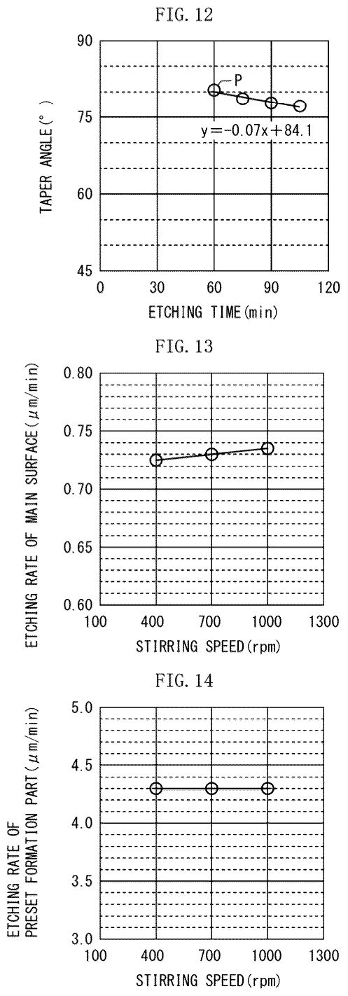

First, measurement was measured on how an inclination angle (taper angle) of an inner wall surface of a through hole to be finally formed in a glass sheet would change with an etching time. The result thereof is shown in FIG. 12.

A point denoted by a reference symbol, “P”, in the drawing represents a taper angle of a preset formation part at the time of penetration of the preset formation part. The taper angle of the preset formation part at the time of penetration thereof changes with the rate of change in the taper angle (−0.07°/min in the example shown in FIG. 12) and an etching time by the time the through hole is finally formed. That is, the taper angle of the through hole is determined by (1) the taper angle of the preset formation part at the time of penetration of the preset formation part, (2) the rate of change in the taper angle of the preset formation part after penetration of the preset formation part, and (3) an etching time.

Subsequently, evaluation was made on how the average relative velocity of an etchant with respect to the glass sheet would affect the taper angle of the through hole to be formed in the glass sheet. The result thereof is shown in FIG. 13 to FIG. 16. The average relative velocity of the etchant with respect to the glass sheet was adjusted by stirring of the etchant with the use of a water bath stirrer. The water bath stirrer is a device that rotates a stirring bar with the use of magnetic force, to stir a liquid such as an etchant.

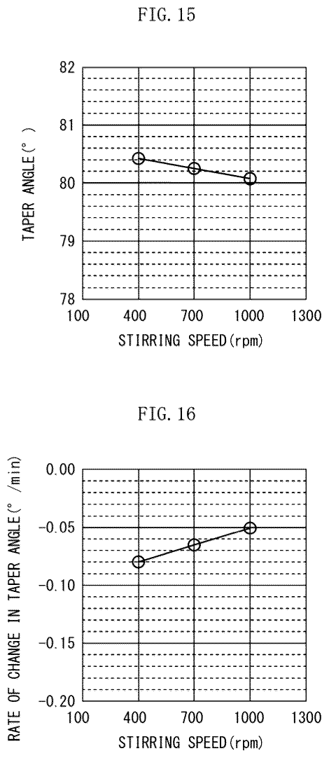

As shown in FIG. 13, before the preset formation part penetrates, the etching rate of a main surface of the glass sheet increases as the stirring speed of the etchant increases. In contrast thereto, as shown in FIG. 14, before the proposed formation penetrates, the etching rate of the preset formation part does not substantially change even when the stirring speed of the etchant is increased. Further, as shown in FIG. 15, the taper angle of the preset formation part at the time of penetration of the preset formation part decreases as the stirring speed of the etchant increases. Those results have revealed that an increase in the stirring speed of the etchant before penetration of the preset formation part promotes only etching of a part near the main surface of the glass sheet, making the taper angle of the preset formation part at the time of penetration of the preset formation part smaller. Thus, it can be said that it is preferred to reduce the average relative velocity of the etchant with respect to the glass sheet before penetration of the preset formation part.

As shown in FIG. 16, the rate of change in the taper angle of the preset formation part after penetration of the preset formation part changes in the positive direction as the stirring speed of the etchant increases. This result has revealed that an increase in the stirring speed of the etchant after penetration of the preset formation part can cause a change in the positive direction in a change in an angle from the taper angle of the preset formation part at the time of penetration of the preset formation part. Thus, it can be said that it is preferred to increase the average relative velocity of the etchant with respect to the glass sheet after penetration of the preset formation part.

It is clear from the above description that the taper angle of the through hole to be finally formed can be increased by reducing the average relative velocity of the etchant with respect to the glass sheet before penetration of the preset formation part and increasing the average relative velocity of the etchant with respect to the glass sheet after penetration of the preset formation part.

### REFERENCE SIGNS LIST

1 Laser device
2 glass sheet
2a first main surface
2b second main surface
3 preset formation part
3a inner wall surface
4 modified part
5, etching vessel
6 etchant
7 stirring member
8 recessed portion
9 through hole
10 etching vessel
11 conveying device
12 first area
13 second area
14 partition wall
15 nozzle
16 conveying device
17 first area
18 second area
L laser light
S1 modifying step
S2 etching step
S2a first etching step
S2b second etching step
θ1 inclination angle (taper angle) of inner wall surface of preset formation part
θ2 inclination angle (taper angle) of inner wall surface of through hole

1. A method for manufacturing a glass sheet having a first main surface, a second main surface, and a through hole penetrating between the first main surface and the second main surface, the method comprising:
a modifying step of modifying a preset formation part for the through hole by irradiation of laser light; and
an etching step of etching the glass sheet while immersing the glass sheet in an etchant, to form the through hole in the preset formation part, after the modifying step,
wherein the etching step comprises:
a first etching step of etching the glass sheet in which the preset formation part does not penetrate; and
a second etching step of etching the glass sheet in which the preset formation part penetrates, after the first etching step, and
wherein an average relative velocity of the etchant with respect to the glass sheet in the second etching step is higher than that in the first etching step.

2. The method for manufacturing a glass sheet according to claim 1, wherein the second etching step is started when the preset formation part penetrates.

3. The method for manufacturing a glass sheet according to claim 1,
wherein, in the etching step, the etchant is stirred, and
wherein an average stirring speed of the etchant in the second etching step is higher than that in the first etching step.

4. The method for manufacturing a glass sheet according to claim 1,
wherein, in the etching step, the glass sheet is moved in the etchant, and
wherein an average movement speed of the glass sheet in the second etching step is higher than that in the first etching step.

5. A method for manufacturing a glass sheet having a first main surface, a second main surface, and a through hole penetrating between the first main surface and the second main surface, the method comprising:
a modifying step of modifying a preset formation part for the through hole by irradiation of laser light; and
an etching step of performing etching by jetting an etchant to each of the first main surface and the second main surface, to form the through hole in the preset formation part, after the modifying step,
wherein the etching step comprises:
a first etching step of etching the glass sheet in which the preset formation part does not penetrate; and
a second etching step of etching the glass sheet in which the preset formation part penetrates, after the first etching step, and
wherein an average jetting pressure of the etchant to the glass sheet in the second etching step is higher than that in the first etching step.

6. The method for manufacturing a glass sheet according to claim 5, wherein the second etching step is started when the preset formation part penetrates.
